(19) United States
(12) Patent Application Publication
(10) Pub. No.: US 2003/0043650 A1
(43) Pub. Date: Mar. 6, 2003

(54) Multilayered memory device

(75) Inventors: Nobuhiro Kato, Tokyo (JP); Muneharu Tokunaga, Tokyo (JP)

Correspondence Address: MCDERMOTT, WILL & EMERY, 600 13th Street, N.W., WASHINGTON, DC, 20005-3096, US

(73) Assignee: Mitsubishi Denki Kabushiki Kaisha

(21) Appl. No.: 10/207,849

(22) Filed: Jul. 31, 2002

(30) Foreign Application Priority Data
Sep. 3, 2001 (JP) 2001-265617

(51) Int. Cl. G11C 7/00

(52) U.S. Cl. 365/200

(57) ABSTRACT

A multilayered memory device with a plurality of BGA packages laminated, which includes a first BGA package and a second BGA package each having ball bumps, a first multilayer board with a wiring pattern connected to the ball bumps on the first BGA package, a second multilayer board with a wiring pattern connected to the ball bumps on the second BGA package, a connecting board provided between the laminated first multilayer board and second multilayer board to connect the wiring pattern included in each of the multilayer boards, and ball bumps provided on the second multilayer board on the side opposite to the side on which said second BGA package is mounted, and connected to the wiring pattern included in the second multilayer board.

### CROSS-REFERENCE TO RELATED APPLICATIONS

A related patent application is a commonly assigned Japanese Patent Application No. 2001-265617 filed on Sep. 3, 2001, which is incorporated by reference into the present patent application.

### BACKGROUND OF THE INVENTION

1. Field of the Invention

The present invention relates to a multilayered memory device, and more particularly to a multilayered memory device with BGA type packages laminated.

2. Description of the Related Art

FIG. 7 is a side view of a conventional multilayered memory device generally denoted at the reference numeral 700. Multilayered memory device 700 includes a plurality of thin small online packages (TSOPs) 710 each having pins 702 provided on the both sides of a package 701 in line. The laminated TSOPs 710 are connected by the soldering pins 702, as shown on the left of FIG. 7, for example. Alternately, the TSOPs 710 are connected by a board 703 with a wiring pattern, as shown on the right of FIG. 7.

However, as ball grid array (BGA) packages have come into use more than TSOPs with an increase in the number of the pins 702, the laminating method as shown in FIG. 7 cannot be used. In other words, having a matrix of ball bumps on one side thereof, BGA packages cannot be formed into the multilayer structure shown in FIG. 7.

### SUMMARY OF THE INVENTION

The present invention, therefore, is directed to provide a multilayered memory device with BGA package type memories laminated.

The present invention provides a multilayered memory device with a plurality of BGA packages laminated. The device includes a first BGA package and a second BGA package each having ball bumps, a first multilayer board with a wiring pattern connected to the ball bumps on the first BGA package, a second multilayer board with a wiring pattern connected to the ball bumps on the second BGA package, a connecting board provided between the laminated first multilayer board and second multilayer board to connect the wiring pattern included in each of the multilayer boards, and ball bumps provided on the second multilayer board on the side opposite to the side on which said second BGA package is mounted, and connected to the wiring pattern included in the second multilayer board.

Also, the present invention provides a multilayered memory device with a plurality of BGA packages laminated. The device includes a first BGA package and a second BGA package each having ball bumps, a multilayer board with wiring patterns on the both sides, and external connection means provided on one side of the multilayer board to be connected to the wiring pattern. The first BGA package and the second BGA package are provided oppositely on both sides of the multilayer board so as to sandwich the multilayer board. The ball bumps included in the first BGA package and the second BGA package are connected to the wiring patterns included in the multilayer board.

Further, the present invention provides a multilayered memory device with a plurality of BGA packages laminated. The device includes a first BGA package and a second BGA package each having ball bumps, a first multilayer board with a wiring pattern connected to the ball bumps on the first BGA package, a second multilayer board with a wiring pattern connected to the ball bumps on the second BGA package, and clip leads for positioning and securing the first multilayer board and the second multilayer board in lamination. The wiring patterns included in the first multilayer board and the second multilayer board are connected to the clip leads.

### BRIEF DESCRIPTION OF THE DRAWINGS

FIG. 1 is a side view of a multilayered memory device in accordance with the first embodiment of the present invention;

FIG. 2 is a side view of a multilayered memory device in accordance with the second embodiment of the present invention;

FIG. 3 is a side view of another multilayered memory device in accordance with the second embodiment of the present invention;

FIG. 4 is a side view of a multilayered memory device in accordance with the third embodiment of the present invention;

FIG. 5 is a side view of another multilayered memory device in accordance with the third embodiment of the present invention;

FIG. 6 is a top view of a memory module in accordance with the fourth embodiment of the present invention; and

FIG. 7 is a side view of a conventional multilayered memory device.

### DETAILED DESCRIPTION OF THE PREFERRED EMBODIMENTS

### First Embodiment

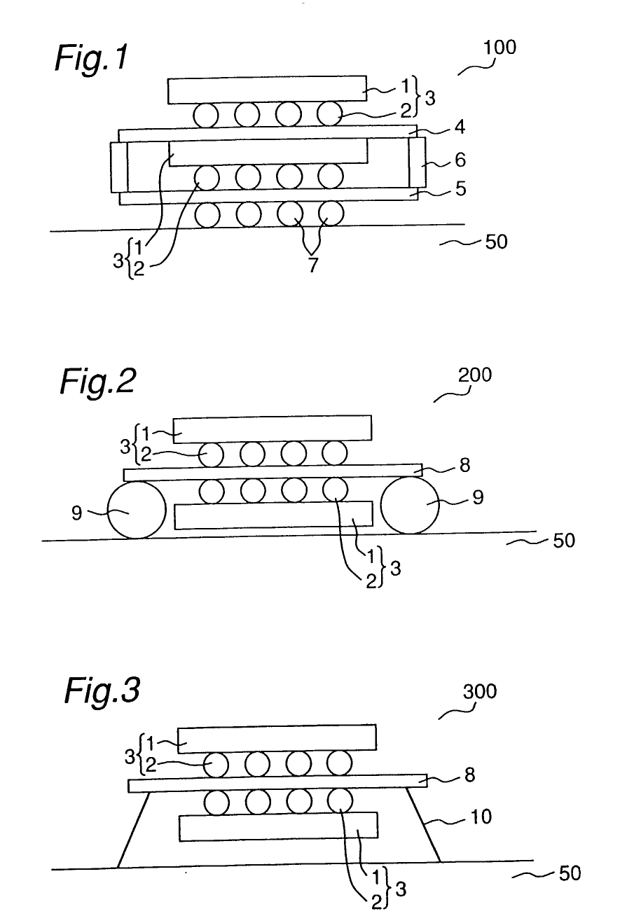

FIG. 1 is a side view of a multilayered memory device in accordance with this embodiment generally denoted at the reference numeral 100.

The multilayered memory device 100 includes ball grid array (BGA) packages 3. The BGA package 3 includes a molded resin 1 having semiconductor elements sealed therein and a matrix of ball bumps 2 provided on the backside of the molded resin 1. Multilayered memory device 100 includes two of the BGA packages 3.

Respective the two BGA packages 3 are placed on multilayer boards 4 and 5. The multilayer boards 4 and 5 have wiring patterns and through holes (not shown) to be connected to the ball bumps 2 on the BGA packages 3, respectively.

The multilayer board 4 is adhered to the backside of the BGA package (second BGA package) 3 via silver paste and the like.

In addition, connecting boards 6 are provided between the multilayer boards 4 and 5. The connecting boards 6 have wiring patterns and through holes.

The BGA package (first BGA package) 3 connected to the multilayer board 4 and the BGA package (second BGA package) 3 connected to the multilayer board 5 are electrically connected via the connecting boards 6.

It is preferable that the area of the multilayer boards 4 and 5 is substantially larger than that of the first and second BGA packages 3 for connection of the connecting boards 6.

Instead of the connecting boards 6, connectors can be used.

Ball bumps 7 are provided on the multilayer board 5 on the side opposite to that with the BGA package mounted on. The ball bumps 7 can be placed in an arrangement similar to that of the ball bumps 2 included in the BGA packages 3. The ball bumps 7 are electrically connected to the two BGA packages 3 via wiring patterns provided on the multilayer board 5.

Therefore, the laminated two BGA packages can be mounted on a mounting board 50 by mounting the multilayered memory device 100 on mounting board 50 using the ball bumps 7.

In this manner, with the multilayered memory device 100 in accordance with the First Embodiment, a multilayered memory device having double memory capacity in the same mounting area can be achieved using the BGA packages 3.

It should be noted that JP, 11-220088, A discloses a multilayer structure with BGA packages laminated, however, this multilayer structure applies to a case where solder balls are formed only on the periphery of a semiconductor chip. This multilayer structure cannot apply to a semiconductor chip with solder balls (the ball bumps 7) formed in a matrix in accordance with this embodiment.

### Second Embodiment

FIG. 2 is a side view of a multilayered memory device in accordance with this embodiment generally denoted at the reference numeral 200.

The multilayered memory device 200 includes first and second BGA packages 3, each having a molded resin 1 and ball bumps 2.

The first and second BGA packages 3 are provided oppositely on the both sides of a multilayer board 8 so as to sandwich the multilayer board 8. The ball bumps 2 are connected to wiring patterns provided on the multilayer board 8.

Provided on one side of the multilayer board 8 are solder balls 9 connected to the wiring pattern of the multilayer board 8. The multilayered memory device 200 is mounted on a mounting board 50 using such solder balls 9.

It is preferable that the area of the multilayer board 8 is larger than that of the molded resin 1 for placing the solder balls 9. It is also preferable that the diameter of the solder ball 9 is larger than the thickness of the BGA package 3 (the sum of the thickness of the molded resin 1 and the diameter of the ball bumps 2) for securing the multilayered memory device 200 onto mounting board 50.

FIG. 3 is a side view of another multilayered memory device in accordance with this embodiment generally denoted at the reference numeral 300. In FIG. 3, the reference numerals same as those in FIG. 2 indicate the same or corresponding elements.

In the multilayered memory device 300, leads 10 are used as external connection means instead of the solder bumps 9 in the multilayered memory device 200 shown in FIG. 2.

In this manner, with the multilayered memory devices 200 and 300 in accordance with the Second Embodiment, multilayered memory devices having double memory capacity in the same mounting area can be achieved using the BGA packages 3.

### Third Embodiment

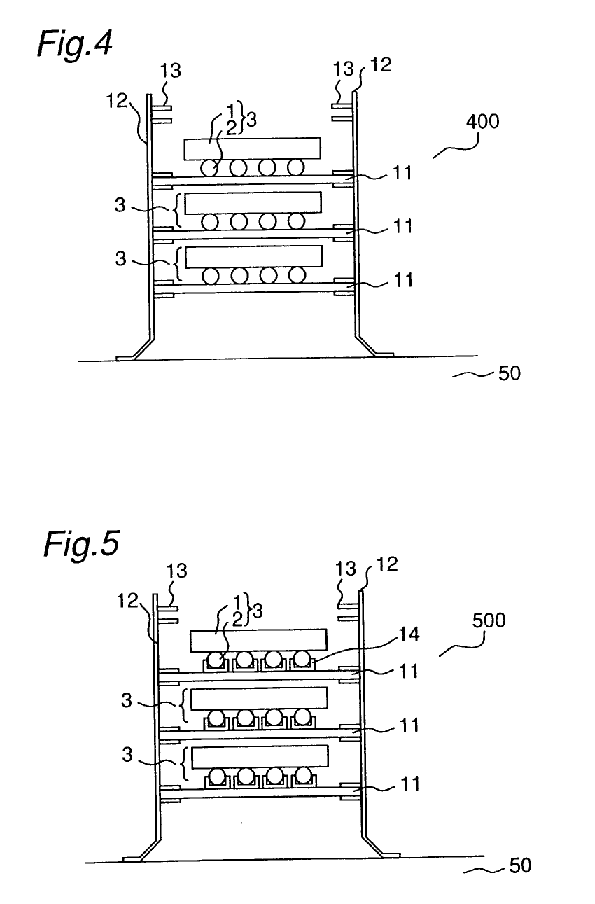

FIG. 4 is a side view of a multilayered memory device in accordance with the Third Embodiment of the present invention generally denoted at the reference numeral 400.

The multilayered memory device 400 includes a plurality of multilayer boards 11. The multilayer board 11 has a BGA package 3 placed thereon. Ball bumps 2 on the BGA package 3 are connected to the wiring pattern on the multilayer board 11.

The plurality of the multilayer boards 11 are secured by clip leads 12 so that they are laminated. On the clip leads 12, a plurality of clip sections 13 are provided for securing the multilayer boards 11 inserted therein. The clip leads 12 are made of a conductive material. By bringing the clip sections 13 and the wiring patterns on the multilayer boards 11 into contact, the clip leads 12 and the wiring patterns are connected.

As shown in FIG. 4, the multilayered memory device 400 is mounted on a mounting board 50 by connecting the clip leads 12 thereto.

FIG. 5 shows another multilayered memory device in accordance with this embodiment generally denoted at the reference numeral 500. In FIG. 5, the reference numerals same as those in FIG. 4 indicate the same or corresponding elements.

As shown in FIG. 5, in the multilayered memory device 500, a plurality of sockets 14 made of a conductive material is provided on a multilayer board 11. The sockets 14 are connected to the wiring patterns provided on the multilayer board 11.

With the multilayered memory device 500, BGA packages 3 are secured to the multilayer boards 11 by inserting ball bumps 2 on the BGA packages 3 into the sockets 14. This configuration facilitates attachment and detachment of the BGA packages 3 to/from the multilayer boards 11.

In this manner, with the multilayered memory devices 400 and 500 in accordance with the Third Embodiment, multilayered memory devices having at least double memory capacity in the same mounting area can be achieved using the BGA packages 3.

### Fourth Embodiment

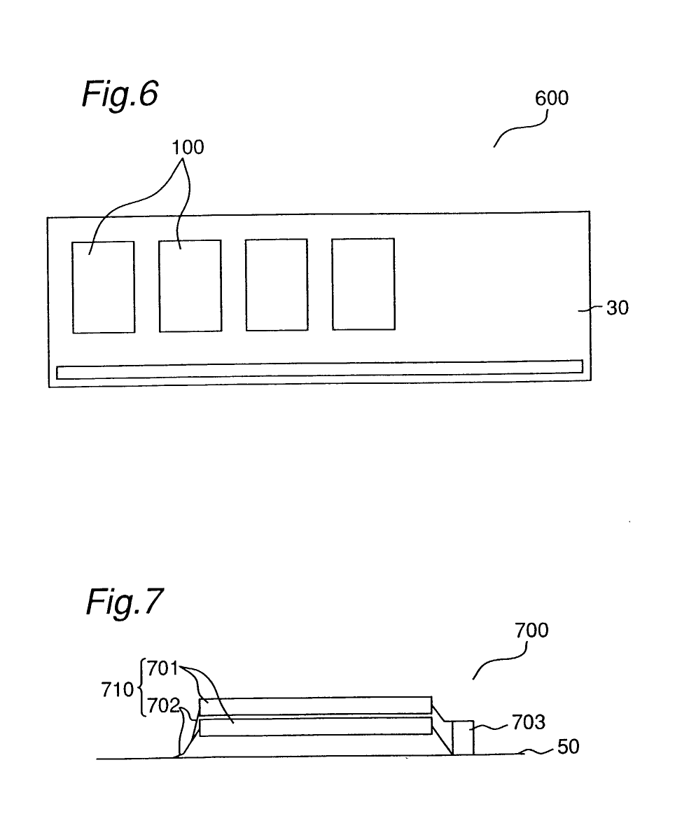

FIG. 6 is a top view of a memory module in accordance with this embodiment generally denoted at the reference numeral 600.

In the memory module 600, a plurality of the multilayered memory devices 100 in accordance with the First Embodiment are placed on motherboard 30. The multilayered memory devices 100 are connected to the wiring pattern (not shown) provided on a motherboard 30.

In the multilayered memory module 600, the multilayered memory devices 200, 300, 400, and 500 in accordance with the Second and Third Embodiments can be placed.

In this manner, with the memory module 600 in accordance with this embodiment, a memory module having large memory capacity can be formed using BGA packages.

What is claimed is:

1. A multilayered memory device with a plurality of ball grid array packages laminated, comprising:
a first BGA package and a second BGA package each having ball bumps;
a first multilayer board with a wiring pattern connected to the ball bumps on the first BGA package;
a second multilayer board with a wiring pattern connected to the ball bumps on the second BGA package;
a connecting board provided between the laminated first multilayer board and second multilayer board to connect the wiring pattern included in each of the multilayer boards; and
ball bumps provided on the second multilayer board on the side opposite to the side on which said second BGA package is mounted, and connected to the wiring pattern included in the second multilayer board.

2. A multilayered memory device according to claim 1, wherein said first multilayer board is adhered to a top face of a resin package included in said second BGA package.

3. A multilayered memory device with a plurality of BGA packages laminated, comprising:
a first BGA package and a second BGA package each having ball bumps;
a multilayer board with wiring patterns on the both sides; and
external connection means provided on one side of the multilayer board to be connected to the wiring pattern,
wherein the first BGA package and the second BGA package are provided oppositely on the both sides of the multilayer board so as to sandwich the multilayer board, and the ball bumps comprised in the first BGA package and the second BGA package are connected to the wiring patterns comprised in the multilayer board.

4. A multilayered memory device according to claim 3, wherein said external connection means comprise a solder ball.

5. A multilayered memory device according to claim 4, wherein a diameter of said solder ball is greater than a thickness of said BGA package.

6. A multilayered memory device according to claim 3, wherein said external connection means comprise a lead.

7. A multilayered memory device with a plurality of BGA packages laminated, comprising:
a first BGA package and a second BGA package each having ball bumps;
a first multilayer board with a wiring pattern connected to the ball bumps on the first BGA package;
a second multilayer board with a wiring pattern connected to the ball bumps on the second BGA package; and
clip leads for positioning and securing the first multilayer board and the second multilayer board in lamination,
wherein the wiring patterns comprised in the first multilayer board and the second multilayer board are connected to the clip leads.

8. A multilayered memory device according to claim 7, wherein said first multilayer board and said second multilayer board are clipped by clip sections provided on said clip leads, and thereby secured to the clip leads.

9. A multilayered memory device according to claim 7, wherein said first multilayer board and/or said second multilayer board include sockets provided on the wiring patterns, and the ball bumps on said first BGA package and/or said second BGA package are inserted into the sockets and thereby connected to the wiring patterns.
